(19) United States
(12) Patent Application Publication
(10) Pub. No.: US 2017/0352798 A1
(43) Pub. Date: Dec. 7, 2017

(54) DIELECTRIC ELECTROACTIVE POLYMER COMPRISING AN ELASTOMERIC FILM IN THE FORM OF A GEL

(71) Applicant: Danmarks Tekniske Universitet, Kgs. Lyngby (DK)

(72) Inventors: Anne Ladegaard SKOV, Frederiksberg (DK); Anders Egede DAUGAARD, Bagsværd (DK)

(73) Assignee: Danmarks Tekniske Universitet, Kgs, Lyngby (DK)

(21) Appl. No.: 15/523,233

(22) PCT Filed: Oct. 29, 2015
(86) PCT No.: PCT/EP2015/075079

§ 371 Date: Apr. 28, 2017

(30) Foreign Application Priority Data
Oct. 31, 2014 (EP) 14191207.1

(51) Int. Cl. H01L 41/193; H01L 41/083; H01L 41/45; H01L 41/09

(52) U.S. Cl. CPC H01L 41/193; H01L 41/45; H01L 41/083; H01L 41/09

(57) ABSTRACT

Use of an elastomeric film in the form of a gel, wherein said gel is a non-conductive hydrogel or organogel, as a dielectric electroactive polymer.

### FIELD OF THE INVENTION

The present invention relates to the use of an elastomeric film in the form of a gel, wherein said gel is a non-conductive hydrogel or organogel, as a dielectric electroactive polymer. The invention relates in particular to the use of an elastomeric film in the form of a gel, wherein said gel is a non-conductive hydrogel or organogel, said gel having very high energy density due to high dielectric permittivity.

### BACKGROUND OF THE INVENTION

Electroactive polymers (EAPs) are polymers that exhibit a change in size or shape when stimulated by an electric field or reversibly generate energy when motioned. Typically, an EAP is able to undergo a major deformation while sustaining large forces.

The development of elastomeric materials with high dielectric permittivity has attracted increased interest over the last years due to their use in e.g. dielectric electroactive polymers (DEAP's).

Dielectric electroactive polymers are materials in which actuation is caused by electrostatic forces on an elastomeric film sandwiched between two electrodes which squeeze the elastomer upon application of an electric field. When an electric voltage is applied, an electrostatic pressure is exerted on the film, reducing its thickness and expanding its area due to the applied electric field. Examples of EAP's are dielectric elastomers. Dielectric electroactive polymers are used e.g. as actuators as so-called “artificial muscles” and as generators in energy-harvesting, such as wave harvesting.

However, a drawback of DEAP's for a wide range of applications is the dielectric permittivity (capability of storing electrical energy) of commonly used elastomers, which needs to be increased significantly in order to obtain higher energy densities for the energy harvesting process to become economically favorable.

WO 2014/086885 A1 discloses dielectric electroactive polymers comprising an ionic supramolecular structure.

WO 2011/094747 A1 discloses a high surface area polymer actuator with gas mitigating components.

EP 2 819 293 A1 discloses a gel actuator and a method for producing same.

Silicone elastomers are currently the DEAP systems with the best over-all performances. Current approaches to enhance the energy density make incremental steps only and a quantum leap is required for the DEAP technology to become viable in a broader area of applications. Most focus in research has been put on the optimization of the dielectric permittivity of the elastomer but many other requirements to the elastomer film also needs consideration such as e.g. high tear strength, high electrical breakdown strength, small viscous loss, small electrical loss, fast actuation speed, high maximum elongation, and a life-time exceeding several million cycles such that the materials will last several years.

The prior art dielectric electroactive PDMS silicone polymers exhibit a relative dielectric permittivity (∈ᵣ) of only about 3-20 at 0.1 Hz and it is envisaged that the energy density of DEAP's should be substantially higher in order to be commercially interesting. Thus the dielectric permittivity seems to be an important tuning parameter for obtaining DEAP's with a high energy density. A further important factor is the Young's modulus which should be as low as possible in order to obtain an improved actuation but which can be of the order of several MPa's for energy harvesting purposes. For actuation in general, the Young's modulus should be <1 MPa.

Ionic electroactive polymers (ionic EAP's) are known, wherein movement of ions may take place within a hydrogel or hydrogel resembling material, cf. http://www-mtl.mit.edu/researchgroups/mems-salon/yawen_Microfabricating_conjugated_polymer_actuators.pdf. This type of actuator is favourable e.g. in cell biology and biomedicine where water is naturally occurring and where a slow operational speed is acceptable. However, for dry, fast conditions the movement of ions is too slow and other materials are required such as dielectric electroactive polymers. Despite the actuation speeds of the dielectric materials, these materials suffer from low energy densities, cf. http://onlinelibrary.wiley.com/doi/10.1002/marc.200900425/abstract. There is therefore a need in the art for a dielectric electroactive polymer having a substantially enhanced relative dielectric permittivity, an enhanced energy density and an improved relative actuation.

### OBJECT OF THE INVENTION

It is an object of embodiments of the invention to provide a dielectric electroactive polymer having a substantially enhanced relative dielectric permittivity and an improved actuation and reliability compared to prior art DEAP's.

### SUMMARY OF THE INVENTION

It has been found by the present inventor(s) that by providing an elastomeric film in the form of a gel, wherein said gel is a non-conductive hydrogel or organogel, an improved dielectric electroactive polymer having a substantially enhanced relative dielectric permittivity and an improved relative actuation and relative reliability may be obtained.

So, in a first aspect the present invention relates to the use of an elastomeric film in the form of a gel, wherein said gel is a non-conductive hydrogel or organogel, as a dielectric electroactive polymer, wherein said gel comprises at least one polymer and a solvent therefor, said at least one polymer being selected from the group consisting of polyalkylene glycol, such as polyethylene glycol or polypropylene glycol, polyvinyl alcohol, poly(acrylic acid), hyaluronan, carbohydrates, silicone and mixtures thereof, and wherein said polymer is present in an amount in the range of 0.5-50% by weight, such as 1-40% by weight, such as 3-30% by weight, such as 4-20% by weight, such as 5-15% by weight, such as 7-10% by weight of the gel. A non-conductive hydrogel or organogel will provide for a non-conductive material with high dielectric permittivity and energy density.

In a second aspect the present invention relates to an elastomeric film in the form of a gel, wherein said gel is a non-conductive hydrogel, for use as a dielectric electroactive polymer, said gel comprising at least one polymer present in an amount in the range of 0.5-50% by weight, such as 1-40% by weight, such as 3-30% by weight, such as 4-20% by weight, such as 5-15% by weight, such as 7-10% by weight of the gel; said polymer being selected from the group consisting of agarose, polyvinyl alcohol, polyethylene glycol, polypropylene glycol, poly(acrylic acid), gelatine, agar agar, pectin, silicone and mixtures thereof; said gel comprising a solvent in the form of deionized water; and said gel further comprising silica particles in combination with particles selected from the group consisting of silicates, metal oxides, clays, carbon, cotton, polyester, polyamide, paper, wood, polymeric microspheres and combinations thereof.

In a third aspect the present invention relates to an elastomeric film in the form of a gel, wherein said gel is a non-conductive organogel, for use as a dielectric electroactive polymer, said gel comprising at least one polymer present in an amount in the range of 0.5-50% by weight, such as 1-40% by weight, such as 3-30% by weight, such as 4-20% by weight, such as 5-15% by weight, such as 7-10% by weight of the gel; said polymer being selected from the group consisting of agarose, polyvinyl alcohol, polyethylene glycol, polypropylene glycol, poly(acrylic acid), gelatine, agar agar, pectin, silicone, and mixtures thereof; said gel comprising a solvent selected from the group consisting of glycerol, alkylene carbonate, such as propylene carbonate, and polyvinyl pyrrolidone, as well as mixtures thereof; and said gel further comprising particles selected from the group consisting of silica, silicates, metal oxides, clays, carbon, cotton, polyester, polyamide, paper, wood, polymeric microspheres and combinations thereof.

In a fourth aspect the present invention relates to a method for the preparation of an elastomeric film according to the invention comprising the steps of:
i) Dissolution or dispersion of at least one polymer in a solvent, optionally by the addition of heat;
ii) adding particles or fibres;
iii) Stabilization of the solution or dispersion obtained to obtain a gel; and
iv) Optionally crosslinking the polymer by means of high energy irradiation or by the addition of a crosslinking agent.

In a fifth aspect the present invention relates to an actuator system comprising at least one negative electrode, at least one positive electrode and at least one elastomeric film according to the invention, wherein said elastomeric film is sandwiched between said at least one negative electrode and said at least one positive electrode.

### DETAILED DISCLOSURE OF THE INVENTION

### Definitions

In the present context the term “elastomer” refers to compositions of matter that have a glass transition temperature, Tg, at which there is an increase in the thermal expansion coefficient, and includes both amorphous polymer elastomers and thermoplastic elastomers (thermoplastics). An elastomer exhibits an elasticity deriving from the ability of the polymer chains of the elastomer to reconfigure themselves to distribute an applied stress.

In the present context the term “elastomeric” refers to a composition of matter having the properties of an “elastomer” as defined above.

In the present context the term “hydrogel” refers to a solid, jelly-like material that can have properties ranging from soft and weak to hard and tough. By weight, gels are mostly liquid, however, due to a three-dimensional cross-linked network they behave like a solid. Hydrogels are composed of water as the solvent and a polymer as the dispersed or dissolved species.

In the present context the term “organogel” refers to a solid, jelly-like material that can have properties ranging from soft and weak to hard and tough. Organogels are composed of an organic solvent, mineral oil or vegetable oil as the solvent and a polymer as the dispersed or dissolved species.

In the present context the term “poly(ethylene glycol)”, abbreviated “PEG”, refers to a compound of the formula HO—CH₂—(CH₂—O—CH₂)ₙ—CH₂—OH, wherein n is from 2 to 150. PEG's are often labelled according to their molecular weight, and thus e.g. PEG 400 refers to a poly(ethylene glycol) having a molecular weight of approximately 400 Daltons.

In the present context the term “poly(propylene glycol)”, abbreviated “PPG”, refers to a compound of the formula HO—CH(CH₃)—CH₂—O—(CH₂—CH(CH₃)—O)ₙ—CH₂—CH(CH₃)—O—CH₂—CH(CH₃)—OH, wherein n is from 2 to 150.

In the present context the term “poly(vinyl alcohol)”, abbreviated “PVA” refers to a compound having repeat units of the formula [CH₂CH[OH)]ₙ, wherein n is the number of repeating units.

In the present context the term “alkyl” means a linear, cyclic or branched hydrocarbon group having 1 to 24 carbon atoms, such as methyl, ethyl, propyl, iso-propyl, cyclopropyl, butyl, iso-butyl, tert-butyl, cyclobutyl, pentyl, cyclopentyl, hexyl, and cyclohexyl.

The term “alkylene” is used in the following to specify moieties derived from alkanes in which two H atoms have been removed to form a diradical species. The simplest alkylene is methylene —CH₂—, and other alkylenes include ethylene —CH₂—CH₂—, propylene —C₃H₆— and butylene —C₄H₈—. The term “alkylene” includes branched, linear and cyclic alkylenes, with linear alkylenes being most preferred.

In the present context the term “hyaluronan”, also called hyaluronic acid or hyaluronate, abbreviated HA, refers to a compound of the formula (C₁₄H₂₁NO₁₁)ₙ, wherein n is the number of repeating units.

In the present context the term “carbohydrate” refers to a compound of the formula Cₘ(H₂O)ₙ, wherein m and n may be different, in particular oligosaccharides and polysaccharides. Non-limiting examples of carbohydrates include agarose, cellulose, starch, dextrin, cyclodextrin, chitosan, gellan, gelatine, pectin, and agar-agar, preferably agarose.

In the present context the term “∈′” is synonomous with the term “∈ᵣ” and stands for relative dielectric permittivity, i.e. the ratio of the amount of electrical energy stored in a material by an applied voltage, relative to that stored in a vacuum. The term “relative dielectric permittivity” is used in the present context interchangeably with the term “relative permittivity”.

In the present context the term “actuation” at a given voltage and a given thickness is proportional to ∈ᵣ/Y, wherein Y is the Young modulus.

In the present context the term “reliability” may be calculated from the figure of merit (fom) ∈ᵣ/Y*BD², wherein Y is the Young's modulus and BD is the maximum electrical field that the elastomer can withstand, i.e. the electrical breakdown field.

In the present context the term “hydrophobicity” refers to the physical property of a substance of repelling a droplet of water. The hydrophobicity of a substance may be quantified by the contact angle. Generally, if the contact angle of water on a surface of a substance is smaller than 90°, the surface is considered hydrophilic, and if the water contact angle is larger than 90°, the solid surface is considered hydrophobic.

### SPECIFIC EMBODIMENTS OF THE INVENTION

In an embodiment of the invention the polymer is selected from the group consisting of agarose, polyvinyl alcohol, polyethylene glycol, polypropylene glycol, poly(acrylic acid), gelatine, agar agar, pectin, silicone and mixtures thereof. Non-limiting, commercially available examples of some of the above include acrylic based elastomers such as VHB 4910 from 3M and silicone (PDMS) based elastomers such as Sylgaard 184 from Dow and Elastosil RT625 from Wacker Chemie which are based on crosslinked PDMS molecules together with reinforcing fillers and/or resins. The above PDMS elastomers may also be functionalised as known in the art, such as with e.g. halogen, such as fluoro, and chloro and alkyl, such as methyl, ethyl, propyl etc.

In an embodiment of the invention the solvent is selected from the group consisting of deionized water, glycerol, alkylene carbonate, such as propylene carbonate, and polyvinyl pyrrolidone, as well as mixtures thereof. A preferred solvent is deionized water or glycerol, preferably deionized water.

In the invention the gel comprises at least one polymer present in an amount in the range of 0.5-50% by weight, such as 1-40% by weight, such as 3-30% by weight, such as 4-20% by weight, such as 5-15% by weight, such as 7-10% by weight of the gel. The amount of polymer used will depend on the specific polymer and whether chemical crosslinking is utilized. Furthermore the amount of polymer may be varied in accordance with any particles or fibres added to the gels depending on the nature and amount of any such particles or fibres.

In an embodiment of the invention the gel further comprises particles selected from the group consisting of particles selected from the group consisting of particles or fibres comprising silica, silicates, metal oxides, clays, carbon, cotton, polyester, polyamide, paper, wood, polymeric microspheres and combinations thereof. Non-limiting examples of metal oxides include TiO₂, CaCu₃Ti₄O₁₂, BaTiO₃, and Ba_{0.7}Sr_{0.3}TiO₃. As non-limiting examples of clays may be mentioned kaolin and attapulgite, as non-limiting examples of silicates may be mentioned basalt, as non-limiting examples of polyamide may be mentioned aramid, and as non-limiting examples of polymeric microspheres may be mentioned silicone microspheres as known in the art, such as disclosed in more detail in González et al., “Encapsulated PDMS Microspheres with Reactive Handles”, Macromol. Mater. Eng. 2014, 299, 729-738.

Hydrogels or organogels may be subject to electromechanical failure or the so-called “pull-in breakdown”, which is a phenomenon caused by electrostatic forces of the electrodes of an actuator system becoming so large that the internal pressure of the elastomer cannot withstand the external electrical pressure. This may lead to short-circuiting of the system and breakdown if the elastomer cannot resist the strong local compression caused by the locally increased electrical force. By incorporating particles into the gel the particle-polymer interactions are believed to decrease the tendency of easy local compression.

In an embodiment of the invention the gel comprises particles of silica, preferably a mixture of particles of silica and one or more metal oxides, such as TiO₂, CaCu₃Ti₄O₁₂, BaTiO₃, and Ba_{0.7}Sr_{0.3}TiO₃, preferably a mixture of particles of silica and TiO₂. Silica—usually fumed—may be used due to the combination of its non-conductive nature and reinforcing nature. Metal oxides such as TiO₂ may be used to further enhance the permittivity due to their high-permittivity nature. Another important function of the particles or fibres is limitation of the ionic movement within the gel such that the actuation of the hydrogel or organogel is initiated by the dielectric nature of the gel rather than by ion diffusion.

In an embodiment of the invention the gel comprises particles or fibres in an amount in the range of 3-25% by weight, such as 5-20% by weight, such as 10-15% by weight of the gel.

The elastomeric film according to the invention may be prepared by dissolving or dispersing the at least one polymer in a solvent, optionally be the addition of heat depending on the polymer and the solvent in question. Any particles or fibres are added, and subsequently the solution or dispersion obtained is stabilized to obtain a gel. Stabilization may in one embodiment take place by several freezing/thawing cycles, such as by 5-20 cycles of freezing at about minus 20 to minus 30 degrees celsius for about 20-25 hours following by thawing at room temperature for 2-5 hours. In another embodiment stabilization may take place by vacuum decompression and drying to constant weight at room temperature. In another embodiment stabilization may be obtained by simple mechanical stirring for a period of time typically ranging from 2-20 hours.

In an embodiment of the invention the polymer of the gel is crosslinked. By introducing or increasing the extent of crosslinking mechanical hysteresis of the gel may be reduced. Crosslinking may take place in a manner known per se. Non-limiting examples thereof include crosslinking by means of high energy irradiation or by the addition of a crosslinking agent. The choice of crosslinking agent will naturally depend on the polymer to be crosslinked. Non-exhaustive examples of common crosslinking agents include aldehydes, carboxylic acids (or derivatives of carboxylic acids), enzymes, divinylsulfones, 1-6-hexamethylenediisocyanate, 1,6-hexanedibromide.

In an embodiment of the actuator system according to the invention the at least one elastomeric film comprises at least two layers having different degrees of hydrophobicity. Thus by having at least two layers of different degrees of hydrophobicity the risk of dielectric breakdown may be minimised and increased stability of the actuator system may be obtained.

In an embodiment of the actuator system according to the invention the at least one elastomeric film comprises one layer having a higher degree of hydrophobicity against one of the electrodes and one layer having a lower degree of hydrophobicity against the other one of the electrodes. As non-limiting examples the elastomeric film according to the invention may comprise one layer of a silicone polymer having a higher degree of hydrophobicity against one of the electrodes and one layer of another silicone polymer having a lower degree of hydrophobicity against the other one of the electrodes.

In an embodiment of the actuator system according to the invention the at least one elastomeric film comprises at least one layer having a lower degree of hydrophobicity arranged between at least two layers having a higher degree of hydrophobicity.

In an embodiment of the actuator system according to the invention the at least one elastomeric film comprises at least one layer having a higher degree of hydrophobicity arranged between at least two layers having a lower degree of hydrophobicity.

In an embodiment of the actuator system according to the invention the at least one elastomeric film comprises layers having a lower degree of hydrophobicity alternating with layers having a higher degree of hydrophobicity. The individual layers may be microstructured, such as by having grooves, patterns etc. in order to increase flexibility.

### Example 1

Preparation of Poly(Vinyl Alcohol) (PVA) Hydrogel

Experimental

A 15 wt. % PVA (polyvinyl alcohol) (Mw=100000)/deionized water hydrogel was prepared after ten days freezing (−26° C. for 21 hours)/thawing (room temperature for 3 hours) cycles of a simple mixture of PVA and deionized water.

The hydrogel was tested on a TA Instrument for linear viscoelastic data and on a dielectric spectrometer for dielectric data. Dielectric relaxation spectroscopy (DRS) was performed on a Novocontrol Alpha-A high-performance frequency analyzer (Novocontrol Technologies GmbH & Co. KG, Germany) operating in the frequency range 10-1-106 Hz at 23° C. The sample diameters tested were 25 mm, while thickness was approximately 0.5-1.0 mm. Results are shown below in Tables 1 and 2.

### Example 2

Preparation of Poly(Vinyl Alcohol) (PVA) Hydrogels with Silica Particles

Experimental

Uniform mixtures of 15 wt. % PVA (polyvinyl alcohol) (Mw=100000) and 10 or 20 wt. % (parts per hundred of hydrogel) silica fillers (hydrophilic, particle size ˜14 nm, Sigma-Aldrich)+75 or 65 wt. % deionized water, respectively, were mixed and vacuum decompression dried to constant weight at room temperature to form stable hydrogels. The hydrogels were tested as indicated above. Results are shown below in Tables 1 and 2.

### Example 3

Preparation of Poly(Vinyl Alcohol) (PVA) Hydrogels with Silica and TiO₂ Particles

Experimental

Uniform mixtures of 15 wt. % PVA (polyvinyl alcohol) (Mw=100000)+10 wt. % SiO₂ fillers (hydrophilic, particle size ˜14 nm, S5505, Sigma-Aldrich)+5 wt. % TiO₂ fillers (hydrophilic, particle size ˜21 nm, P25, Aeroxide)+70 wt. % deionized water or 15 wt. % PVA+10 wt. % SiO₂+10 wt. % TiO₂+65 wt. % deionized water, respectively, were mixed and vacuum decompression dried to constant weight at room temperature to form a stable hydrogels.

### Example 4

Preparation of Poly(Vinyl Alcohol) (PVA)/Glycerol Organogel

Experimental

Two formulations, i.e. 5 wt. % PVA (Polyvinyl alcohol) (Mw=100000 g/mol)/95 wt. % Glycerol 15 wt. % PVA (Polyvinyl alcohol) (Mw=100000 g/mol)/85 wt. % Glycerol were prepared by mixing at 150° C. with mechanical stirring for one day. A gel formed quickly when cooling from 150° C. to room temperature.

The organogels were tested as indicated above. Results are shown below in Tables 1 and 2.

### Example 5

Preparation of Agar Agar Hydrogel

Experimental

Agar Agar (supplied by NATUR DROGERIET) powders were dissolved in hot deionized water at about 95 degrees to get a homogeneous transparent solution. The mass ratio between Agar Agar powder and water is 3.5:750 according to the product data. The uniform mixture formed a gel when cooled at room temperature.

TABLE 1

| | | G′ (kPa) | | | | |
|---|---|---|---|---|---|---|
| | | Formulation | | Relative permittivity εᵣ | | |
| | Breakdown | 0.01 | 100 | 0.1 | 1000 | 1 |
| | (V/μm) | Hz | Hz | Hz | Hz | MHz |
| Reference Elastosil RT625 | 60 | 200 | 200 | 3 | 3 | 3 |
| 15 wt. % PVA + 85 wt. % water | 60 | 10 | 14 | 8.69 × 10⁹ | 1.73 × 10⁶ | 28.9 |
| (deionized) | | | | | | |
| 15 wt. % PVA + 10 wt. % SiO₂ + | 68 | 15 | 54 | 4.39 × 10⁸ | 5.94 × 10⁵ | 17 |
| 75 wt. % water (deionized) | | | | | | |
| 15 wt. % PVA + 20 wt. % SiO₂ + | 73 | 130 | 342 | 4.1 × 10⁸ | 5.2 × 10⁵ | 50.4 |
| 65 wt. % water (deionized) | | | | | | |
| 15 wt. % PVA + 10 wt. % | 73 | 20 | 181 | 5.48 × 10⁸ | 7.36 × 10⁵ | 77.7 |
| SiO₂ + 5 wt. % TiO₂ + | | | | | | |
| 70 wt. % water (deionized) | | | | | | |
| 15 wt. % PVA + 10 wt. % | 79 | 79 | 292 | 8.68 × 10⁸ | 1.17 × 10⁶ | 104 |
| SiO₂ + 10 wt. % | | | | | | |
| TiO₂ + 65 wt. % water (deionized) | | | | | | |
| 5 wt. % PVA + 95 wt. % glycerol | 47 | 1.6 | 2.3 | 1.47 × 10⁷ | 2870 | 63 |
| 15 wt. % PVA + 85 wt. % glycerol | 40 | 39 | 129 | 8.69 × 10⁶ | 270 | 45 |
| 0.5 wt % agar agar + 99.5 wt % | 62 | 0.73 | 1.2 | 4.44 × 10⁷ | 4.02 × 10³ | 79.3 |
| water (deionized) | | | | | | |

For actuation purposes ∈ᵣ/Y*BD̂2, i.e. the parameter “reliability”, is the figure of merit (fom). The best available processable material, RTV silicone elastomer Elastosil RT625 V/um, commercially available from Wacker, Germany, has ∈ᵣ=3, Y=0.6 MPa and BD=60 V/um, which gives a fom=18.000. Below the figures of merit have been normalized with this value (i.e. the numbers indicate how many times better the materials perform when evaluated by these parameters).

TABLE 2

| | Normalized figure of merit actuation | | |
|---|---|---|---|
| Formulation | 0.1 Hz | 1000 Hz | 1M Hz |
| Reference Elastosil RT625 | 1 | 1 | 1 |
| 15 wt. % PVA + 85 wt. % water | 5.79E+10 | 1.15E+07 | 192.67 |
| (deionized) | | | |
| 15 wt. % PVA + 10 wt. % SiO₂ + | 2.51E+09 | 3.39E+06 | 97.05 |
| 75 wt. % water (deionized) | | | |
| 15 wt. % PVA + 20 wt. % SiO₂ + | 3.11E+08 | 3.95E+05 | 38.26 |
| 65 wt. % water (deionized) | | | |
| 15 wt. % PVA + 10 wt. % | 2.70E+09 | 3.63E+06 | 383.39 |
| SiO₂ + 5 wt. % | | | |
| TiO₂ + 70 wt. % water (deionized) | | | |
| 15 wt. % PVA + 10 wt. % | 1.27E+09 | 1.71E+06 | 152.15 |
| SiO₂ + 10 wt. % | | | |
| TiO₂ + 65 wt. % water (deionized) | | | |
| 5 wt. % PVA + 95 wt. % glycerol | 3.76E+08 | 7.34E+04 | 1.61E+03 |
| 15 wt. % PVA + 85 wt. % glycerol | 6.60E+06 | 205.13 | 34.19 |
| 0.5 wt % agar agar + 99.5 wt % | 4.33E+09 | 3.92E+05 | 7.73E+03 |
| water (deionized) | | | |

1. Use of an elastomeric film in the form of a gel, wherein said gel is a non-conductive hydrogel or organogel, as a dielectric electroactive polymer, wherein said gel comprises at least one polymer and a solvent therefor, said at least one polymer being selected from the group consisting of polyalkylene glycol, such as polyethylene glycol or polypropylene glycol, polyvinyl alcohol, poly(acrylic acid), hyaluronan, carbohydrates, silicone and mixtures thereof, and wherein said polymer is present in an amount in the range of 0.5-50% by weight, such as 1-40% by weight, such as 3-30% by weight, such as 4-20% by weight, such as 5-15% by weight, such as 7-10% by weight of the gel.

2. The use according to claim 1, wherein the polymer is selected from the group consisting of agarose, polyvinyl alcohol, polyethylene glycol, polypropylene glycol, poly(acrylic acid), gelatine, agar agar, pectin, silicone and mixtures thereof.

3. The use according to claim 1, wherein the solvent is selected from the group consisting of deionized water, glycerol, alkylene carbonate, such as propylene carbonate, and polyvinyl pyrrolidone, as well as mixtures thereof.

4. The use according to claim 1, wherein the gel further comprises particles or fibers selected from the group consisting of particles or fibers comprising silica, silicates, metal oxides, clays, carbon, cotton, polyester, polyamide, paper, wood, polymeric microspheres and combinations thereof.

5. The use according to claim 4, wherein the gel comprises particles of silica, preferably a mixture of particles of silica and one or more metal oxides, such as TiO₂, CaCu₃Ti₄O₁₂, BaTiO₃, and Ba_{0.7}Sr_{0.3}TiO₃, preferably a mixture of particles of silica and TiO₂.

6. The use according to claim 4, wherein the gel comprises particles or fibers in an amount in the range of 3-25% by weight, such as 5-20% by weight, such as 10-15% by weight of the gel.

7. The use according to claim 1, wherein the polymer of the gel is crosslinked.

8. An elastomeric film in the form of a gel, wherein said gel is a non-conductive hydrogel, for use as a dielectric electroactive polymer, said gel comprising at least one polymer present in an amount in the range of 0.5-50% by weight, such as 1-40% by weight, such as 3-30% by weight, such as 4-20% by weight, such as 5-15% by weight, such as 7-10% by weight of the gel; said polymer being selected from the group consisting of agarose, polyvinyl alcohol, polyethylene glycol, polypropylene glycol, poly(acrylic acid), gelatine, agar agar, pectin, silicone, and mixtures thereof; said gel comprising a solvent in the form of deionized water; and said gel further comprising silica particles in combination with particles or fibers selected from the group consisting of silicates, metal oxides, clays, carbon, cotton, polyester, polyamide, paper, wood, polymeric microspheres and combinations thereof.

9. An elastomeric film in the form of a gel, wherein said gel is a non-conductive organogel, for use as a dielectric electroactive polymer, said gel comprising at least one polymer present in an amount in the range of 0.5-50% by weight, such as 1-40% by weight, such as 3-30% by weight, such as 4-20% by weight, such as 5-15% by weight, such as 7-10% by weight of the gel; said polymer being selected from the group consisting of agarose, polyvinyl alcohol, polyethylene glycol, polypropylene glycol, poly(acrylic acid), gelatine, agar agar, pectin, silicone, and mixtures thereof; said gel comprising a solvent selected from the group consisting of glycerol, alkylene carbonate, such as propylene carbonate, polyvinyl pyrrolidone; and said gel further comprising particles or fibers selected from the group consisting of silica, silicates, metal oxides, clays, carbon, cotton, polyester, polyamide, paper, wood, polymeric microspheres and combinations thereof.

10. The elastomeric film according to claim 8 or 9, wherein said gel comprises particles or fibers in an amount in the range of 3-25% by weight, such as 5-20% by weight, such as 10-15% by weight of the gel.

11. A method for the preparation of an elastomeric film in the form of a gel according to any one of claim 8 or 9 comprising the steps of:
i) Dissolution or dispersion of at least one polymer in a solvent, optionally by the addition of heat;
ii) adding particles or fibers;
iii) Stabilization of the solution or dispersion obtained to obtain a gel; and
iv) Optionally crosslinking the polymer by means of high energy irradiation or by the addition of a crosslinking agent.

12. An actuator system comprising at least one negative electrode, at least one positive electrode and at least one elastomeric film according to any one of claim 8 or 9, wherein said elastomeric film is sandwiched between said at least one negative electrode and said at least one positive electrode.

13. The actuator system according to claim 12, wherein the at least one elastomeric film comprises at least two layers having different degrees of hydrophobicity.

14. The actuator system according to claim 12, wherein the at least one elastomeric film comprises at least one layer having a lower degree of hydrophobicity arranged between at least two layers having a higher degree of hydrophobicity.

15. The actuator system according to claim 12, wherein the at least one elastomeric film comprises layers having a lower degree of hydrophobicity alternating with layers having a higher degree of hydrophobicity.
